(19) United States
(12) Patent Application Publication
(10) Pub. No.: US 2008/0060579 A1
(43) Pub. Date: Mar. 13, 2008

(54) Apparatus of triple-electrode dielectric barrier discharge at atmospheric pressure

(75) Inventors: Cheng-Chang Hsieh, Chiayi City (TW); Mien-Win Wu, Longtan Township (TW); Chi-Fong Ai, Longtan Township (TW)

Correspondence Address: TROXELL LAW OFFICE PLLC, 5205 LEESBURG PIKE, SUITE 1404, FALLS CHURCH, VA, 22041, US

(73) Assignee: ATOMIC ENERGY COUNCIL-INSTITUE OF NUCLEAR ENERGY RESEARCH, Taoyuan (TW)

(21) Appl. No.: 11/510,824

(22) Filed: Aug. 28, 2006

(51) Int. Cl. C23C 16/00

(52) U.S. Cl. 118/715

(57) ABSTRACT

A dielectric barrier discharge uses three electrodes at an atmospheric pressure. A wide discharge gap can be used and an enhanced plasma density can be achieved so that thick materials can be processed and its processing speed can also be greatly improved.

### FIELD OF THE INVENTION

The present invention relates to an apparatus of a dielectric barrier discharge for generating glow discharge plasmas at atmospheric pressure; more particularly, relates to obtaining more stable glow discharge plasmas, wider discharge gap and a higher plasma density to speed up material processing and to process thick materials.

### DESCRIPTION OF THE RELATED ART

The word “plasma” is used to describe partially ionized gases containing many interacting free electrons, ionized atoms or molecules and free radicals. Non-thermal equilibrium plasma has many applications such as surface modification of polymers, cleaning, etching and thin film deposition. It is known that plasma sources operated at atmospheric pressure have many advantages such as free of vacuum chamber, the potential to achieve higher processing speed and lower processing cost, etc.

The conventional dielectric barrier discharge (DBD) reactor consists of two electrodes with at least one dielectric barrier, high voltage power supplies, a gas flow system and diagnostic instruments. In which, the high voltage AC power supply is used to excite a capacitive load to generate plasma. The plasma generated using such a prior art is commonly employed for the surface treatment of sheet materials. However, DBD was usually operated in the filamentary mode and only under some special conditions, a glow discharge mode is available, which is highly desired for uniform surface treatment. Besides, there are many other issues in surface processing by DBD, such as narrow discharge gap and low plasma density. Hence, the prior art does not meet most of users' requirements in practical applications.

### SUMMARY OF THE INVENTION

The main purpose of the present invention is to generate stable glow discharge plasmas, to speed up material processing and to process thick materials by increasing the atmospheric pressure plasma density with two properly correlated high voltage power supplies so that the device could be operated in glow discharge mode at a wide discharge gap.

To achieve the above purpose, the present invention is an apparatus of triple-electrode dielectric barrier discharge (TDBD) at an atmospheric pressure, comprising a plasma chamber, a first power supply, a second power supply, a mass flow controller, a first electrode, a second electrode, a common ground electrode with respect to the first and the second electrode and a dielectric layer and a discharge gap; the first electrode together with the common ground electrode is connected to the first power supply; the second electrode together with the common ground electrode is connected to the second power supply; Therein, the mass flow controller provides and controls various gas in the plasma chamber flowing through the discharge gap to generate discharge plasmas on the surface of the first electrode; the charged particles on the surface of the 1^{st} electrode are attracted by the 2^{nd} electrode so that its discharge could be ignited at lower applied voltage and wider discharge gap than the conventional DBD. Thus, the discharge on the 2^{nd} electrode becomes much easier due to the help of the pre-ionization plasmas generated on the surface of the 1^{st} electrode; and, therefore, the discharge gap can be widened in order to process thick material and to speed up material processing. Accordingly, a novel apparatus of triple-electrode dielectric barrier discharge at an atmospheric pressure is obtained, which could be used to treat thick materials and to speed up its processing.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the schematic showing the preferred embodiment according to the present invention;

FIG. 2 shows the relative intensity of optical emission at various delay time; and

FIG. 3 illustrates the ratio of plasma intensity and input power.

### DESCRIPTION OF THE PREFERRED EMBODIMENT

The following description of the preferred embodiment is provided to understand the features and the structures of the present invention.

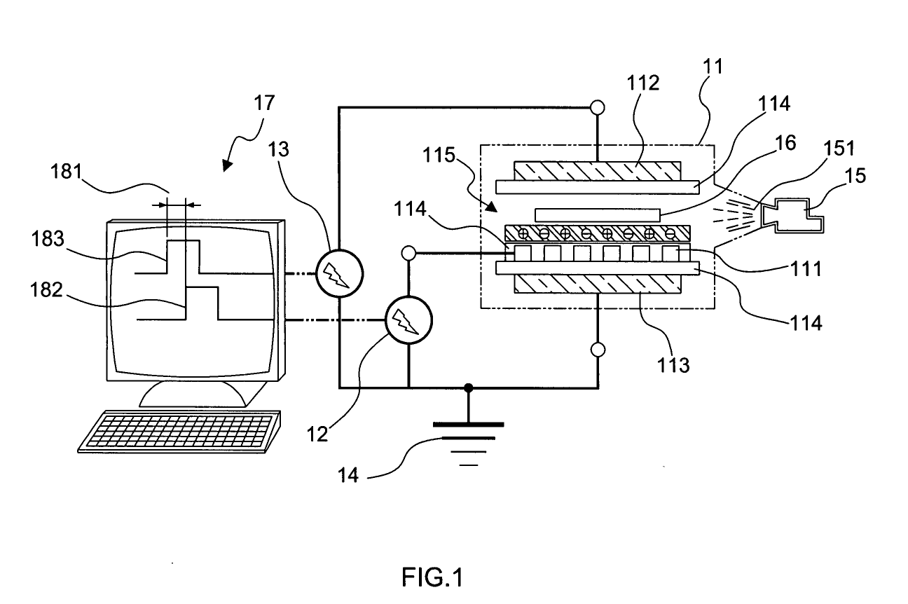

Please refer to FIG. 1, which is a schematic for the preferred embodiment according to the present invention. As shown in the figure, the present invention is an apparatus of triple-electrode dielectric barrier discharge at an atmospheric pressure, comprising a plasma chamber 11, a first power supply 12, a second power supply 13, 14, a mass flow controller 15, a first electrode 111, a common ground electrode, a second electrode 112, a plurality of dielectric layers 114 and a discharge gap 115, where the first electrode 111 is together with the common ground electrode 113 is connected to the first power supply 12; the second electrode 112 together with the common ground electrode 113 is connected to the second power supply 113; The discharge gap 115 is located above the surface of the dielectric layer 114 on the first electrode 111.

The plasma chamber 11 is connected to the input of a mass flow controller 15; and, the substrate 16 to be treated is placed on the dielectric layer 114 in the discharge gap 115. Plasma working gas 151 is filled into the plasma chamber 11 by the mass flow controller 15. On operating the present invention, a surface discharge is formed on the surface of dielectric layer 114 of the first electrode 111. Then charged particles on a surface of the dielectric layer 114 are attracted by the second electrode 112 to produce plasmas in the gap between the 2^{nd} electrode and the common ground electrode. Thus, a novel apparatus of triple-electrode dielectric barrier discharge at an atmospheric pressure is obtained.

When using the present invention, the first power supply 12 and the second power supply 13 are each connected to first electrode 111 and second electrode 112; when the first electrode 111 is applied with a power from the first power supply 12, surface discharge plasma is formed on the surface of the dielectric layer 114. After a delay time 183, the second electrode 112 is applied with a voltage pulse from the second power supply 13 and the charged particles generated in the surface discharge plasma filled in the discharge gap 115 are to generate glow discharge plasma. Then, the plasma monitor 17 precisely figures out proper delay time 183 to enhance the plasma density. Thus, the discharge gap 115 can be widened to process thick materials.

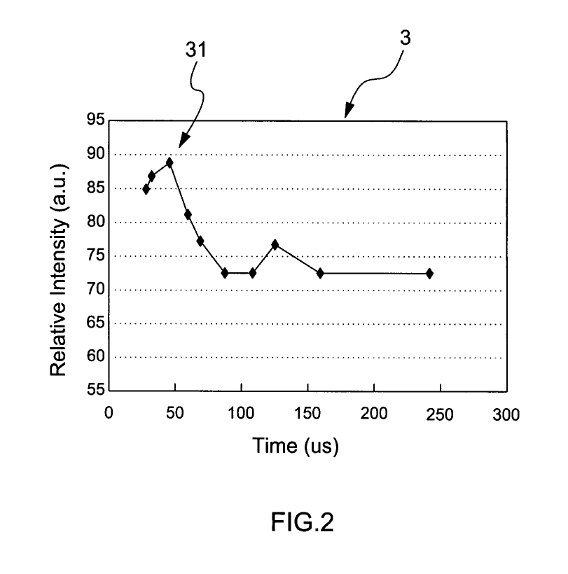

Please refer to FIG. 2, which shows the relative intensity of optical emission at various delay times. As shown in the figure, when applying the present invention, 2 slm of nitrogen is filled in a 10-mm discharge gap under an atmospheric pressure the relative intensity of optical emission line 3 for nitrogen molecules at a wavelength of 316 nm is measured. And it is clearly shown that the optical emission line 31 varies significantly for different delay time between the first pulse and the second pulse. As shown in the optical mission line 31, when the pulse delay time is 40 μs, the intensity is about 90, which is much higher than 63.2 for a conventional two-electrode dielectric barrier discharge. Hence, triple-electrode dielectric barrier discharge has a higher discharge plasma density than the two-electrode one, where the total power intensity can be doubled by applying two closely correlated power sources at the same discharge area.

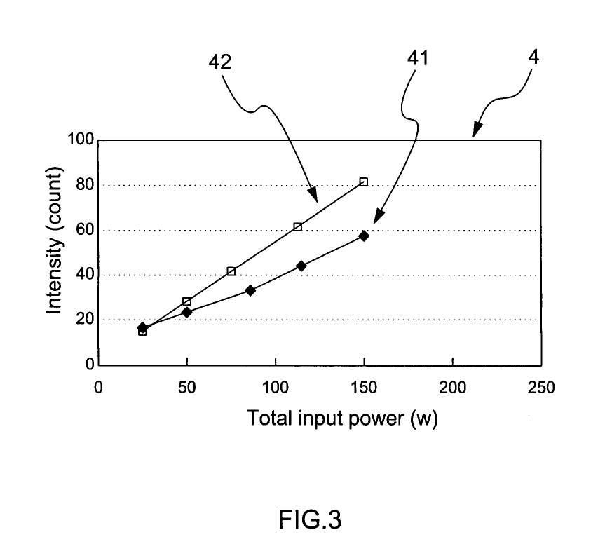

Please refer to FIG. 3, which shows the ratio of the emission intensity and its total input power at various power for a conventional two-electrode DBD 41 and the (a) triple-electrode DBD 42 with the same total input power. As shown in the figure, the emission intensity per unit power 42 for the triple-electrode DBD (42) is higher than that 41 for the conventional two-electrode DBD (41).

To sum up, the present invention is an apparatus of triple-electrode dielectric barrier discharge at an atmospheric pressure where a wide discharge gap can be used at an atmospheric pressure and its plasma density can be greatly enhanced for processing thick materials and speeding up the processing.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An apparatus of triple-electrode dielectric barrier discharge at an atmospheric pressure, comprising:
a plasma chamber;
a first electrode;
a second electrode;
a common ground electrode;
a first power supply;
a second power supply;
a mass flow controller;
a plurality of dielectric layers; and
a mass flow controller, said mass flow controller providing plasma gases to obtain said pre-ionization plasmas.

2. The barrier discharge apparatus according to claim 1,
wherein said plasma chamber is equipped with a plasma monitor and an input of plasma gas.

3. The barrier discharge apparatus according to claim 1,
wherein said first electrode and said second electrode are applied by a first high voltage pulse and a second high voltage pulse separately.

4. The barrier discharge apparatus according to claim 3,
wherein a pulse delay time and a phase lag can be varied between the 1^{st} pulse input of said first electrode and the 2^{nd} pulse input of said second electrode.

5. The barrier discharge apparatus according to claim 4,
wherein the voltage pulse for either said first pulse or said second pulse is a modulated pulse selected from a direct-circuit (DC) pulse, an alternating-circuit (AC) pulse, a radio frequency (RF) pulse and a microwave pulse.
